(19) United States
(12) Patent Application Publication
(10) Pub. No.: US 2009/0002878 A1
(43) Pub. Date: Jan. 1, 2009

(54) Method of Producing a Magnetic Recording Medium

(75) Inventor: Masahiro Oka, Yokohama-shi (JP)

Correspondence Address: SUGHRUE MION, PLLC, 2100 PENNSYLVANIA AVENUE, N.W., SUITE 800, WASHINGTON, DC, 20037, US

(73) Assignee: Showa Denko K.K., Tokyo (JP)

(21) Appl. No.: 11/658,743

(22) PCT Filed: Jul. 25, 2005
(86) PCT No.: PCT/JP05/13990

§ 371 Date: Jan. 29, 2007

Related U.S. Application Data
(60) Provisional application No. 60/599,862, filed on Aug. 10, 2004.

(30) Foreign Application Priority Data
Jul. 30, 2004 (JP) 2004-224374

(51) Int. Cl. C23C 14/00; G11B 5/62; G11B 5/78; G11B 5/52

(52) U.S. Cl. 360/83; 428/800; 204/192.1; 360/134; G9B/5.291; G9B/5.173

(57) ABSTRACT

The present invention is characterized by the fact that a non-magnetic substrate 11, target members 12, and magnetic plates 21 are placed in parallel in a film-forming apparatus 10, a high frequency voltage is applied to the target members, the opposite polarities alternately occur at equal intervals on the surfaces of the magnetic plates, and plasma is produced near the target members to deposit a thin film on the non-magnetic substrate by sputtering. The present invention can greatly increase the track density and, accordingly, the surface recording density while maintaining the recording/reproduction properties equal to or better than that of the prior art.

Priority is claimed on Japanese Patent Application No. 2004-224374, filed Jul. 30, 2004, the content of which is incorporated herein by reference. And, priority is claimed on U.S. provisional application No. 60/599,862, filed Aug. 10, 2004, the content of which is incorporated herein by reference.

### TECHNICAL FIELD

The present invention relates to a magnetic recording medium used, for example, with a hard disk device, a method of producing the magnetic recording medium, and a magnetic recording device provided with the magnetic recording medium.

### BACKGROUND ART

Recently, magnetic recording devices, such as magnetic disks, floppy (registered trademark) disk, and magnetic tape devices, have been increasingly extensively used. With their increasing importance, attempts have been made to greatly improve the recording densities of magnetic recording media. Particularly, since the introduction of MR heads (magneto-resistive heads) and PRML (partial response maximum likelihood) technique, the surface recording density has been significantly increased. In addition, following the recent introduction of GMR heads (giant magneto-resistive heads) and TMR heads (tunnel magneto-resistive heads), surface recording density has been increased approximately 100% annually.

Such magnetic recording devices continuously require higher recording densities. Therefore, magnetic recording layers having a higher level of magnetic retention, a higher signal-to-noise ratio (SN ratio), and high resolution are required. Recent attempts to improve the surface recording density involve increasing track density in addition to improving line recording density. Current magnetic recording devices have a track density of 110 kTPI.

However, magnetically recorded information on adjacent tracks interferes with itself along with increased track densities and noise may occur in the magnetic transition region at their borders, impairing the SN ratio. This directly results in worsening of the bit error rate, which is a drawback to improving the recording density.

Because of the small distance between tracks, the magnetic recording device requires highly precise track servo techniques and reproduction has to be performed in a smaller width than recording in order to eliminate as much influence as possible from adjacent tracks, thereby minimizing inter-track influence. On the other hand, it is difficult to obtain sufficient reproduction output; therefore, the SN ratio is difficult to assure.

In one of the attempts to resolve the problems above, a concave-convex pattern is formed on the recording medium surface along tracks to physically separate the tracks and to improve the track density. Such a technique is hereafter referred to as the discrete track technique.

The discrete track technique includes two methods: one in which a magnetic recording medium having multiple layers is formed, followed by the formation of the tracks, and another in which a concave-convex pattern is formed directly on the surface of a substrate or on a thin film layer provided for forming the tracks, followed by the formation of a thin film for a magnetic recording medium. Among these, the latter is knows as the pre-emboss method. The pre-emboss method has the advantage that the physical processing on the medium surface is completed before the medium is formed. Therefore, the production process is simplified and the medium is unlikely to become contaminated in the production processes. However, the concave-convex pattern formed during pre-embossing is not well preserved because a thin film grows in any direction during medium film-forming, making it difficult to physically separate the tracks when they have a small pitch.

Patent Document 1: Japanese Unexamined Patent Application, First Publication No. 2001-274143

Patent Document 2: Japanese Unexamined Patent Application, First Publication No. 2002-15418

### DISCLOSURE OF INVENTION

The present invention aims to greatly improve track density and, accordingly, the surface recording density in a magnetic recording device that is facing technical difficulties in the prior art along with increased track density while maintaining recording/reproducing properties equal to or better than those of the prior art.

It is an objective of the present invention to provide a useful discrete track magnetic recording medium in which a concave-convex pattern is preserved after film-forming in a discrete track magnetic recording medium of the pre-emboss type.

The present invention provides a method of producing a discrete track magnetic recording medium in which particles sputtered and released from targets orthogonally enter a substrate during film-forming so that a thin film is formed on physically discrete, discontinuous tracks, whereby the magnetic influence of adjacent tracks is completely eliminated, increasing the track density and, accordingly, the surface recording density of the magnetic recording medium.

The present invention relates to the following.

The present invention provides a method of producing a discrete magnetic recording medium having physically discrete magnetic recording tracks and servo signal patterns on at least one surface of a non-magnetic substrate, characterized by the fact that the non-magnetic substrate, target members on either surface of the non-magnetic substrate, and magnetic plates on the opposite surface of each target member to the substrate are placed in parallel in a film-forming apparatus, a high frequency voltage is applied to the target members, opposite polarities alternately occur at regular intervals on the surfaces of the magnet plates, and a sputtering gas is introduced in the film-forming apparatus to produce plasma near the target members, thereby forming a thin film on the non-magnetic substrate.

In the present invention, the plasma near the non-magnetic substrate placed in the film-forming apparatus has a density of 1×10¹¹/cm³ or larger.

The present invention is characterized by the fact that a high frequency voltage bias is applied to the non-magnetic substrate.

In the present invention, a direct current voltage can be applied to the target members in addition to the high frequency voltage.

It is preferred in the present invention that a higher frequency be applied to the target members than to the substrate.

The present invention can be characterized by the fact that the magnet plates are rotated, and by the fact that the non-magnetic substrate has a concave-convex pattern directly formed on at least one surface or formed on a thin film on at least one surface.

The present invention provides a magnetic recording medium produced by the method of producing a discrete magnetic recording medium according to any one of above aspects.

The present invention provides a magnetic recording device comprising a combination of the magnetic recording medium according to above aspects, a driving part for driving the magnetic recording medium in the recording direction, a magnetic head consisting of a recording part and a reproducing part, a means for moving the magnetic head relative to the magnetic recording medium, and a recording/reproducing signal processing means for supplying input signals to the magnetic head and reproducing output signals from the magnetic head.

The present invention can provide a discrete track magnetic recording medium produced by the pre-emboss technique, utilized to industrial advantage, and having excellently discrete tracks, with no influence of signal interference between adjacent tracks, and a high recording density.

### BRIEF DESCRIPTION OF THE DRAWINGS

FIG. 1 shows the production method according to the present invention in a sequence of processes. FIG. 1A is a cross-section showing a pre-emboss layer formed on a substrate. FIG. 1B is a cross-section showing a concave-convex pattern formed on the pre-emboss layer. FIG. 1C is a cross-section showing a magnetic layer formed on the concave-convex pattern. FIG. 1D is a cross-section showing a non-magnetic layer formed on the concave-convex pattern.

FIG. 2 shows the production method according to the present invention in the sequence of processes. FIG. 2A is a cross-section showing the surface of the non-magnetic layer shown in FIG. 1(d) being partly etched. FIG. 2B is a cross-section showing the state after the non-magnetic layer on the magnetic layer is removed.

FIG. 2C is a cross-section showing the state after a protection layer is formed.

FIG. 3 is an illustration showing the structure of a film-forming apparatus used in the method according to the invention.

FIG. 4 is an illustration showing an arrangement of magnets of a magnet plate used in the film-forming apparatus shown in FIG. 3.

In the figures shown are a substrate 1, a pre-emboss layer 2, a concave-convex pattern 3, a non-magnetic concave part 3a, a convex part 3b, a protective layer 4, a recording layer 5, a non-magnetic layer 8, a non-magnetic filling 9, a film-forming apparatus 10, a non-magnetic substrate 11, target members 12, a sputtering gas 13, magnet plates 21, a high frequency power source 22, a bias power source 23, a feed port 15, and an exhaust pipe 16.

### BEST MODE FOR CARRYING OUT THE INVENTION

The method of producing a discrete magnetic recording medium of the present invention is described in detail hereafter.

Any magnetic film structures of magnetic recording media currently widely used are applicable and the magnetic film structure does not affect the forming of discontinuous tracks of the present invention.

The magnetic recording medium of the present invention can be a longitudinal magnetic recording medium or a perpendicular magnetic recording medium. The non-magnetic substrate used in the magnetic recording medium of the present invention can be a substrate made of an Al based alloy such as an Al—Mg alloy, conventional soda glass, aluminosilicate glass, amorphous glass, silicon, titan, ceramics, and a variety of resins. Any non-magnetic substrate can be used. Among them, an Al alloy substrate or a glass substrate such as a crystallized glass substrate and an amorphous glass substrate is preferably used.

The process of producing a magnetic disk generally starts with cleaning and drying a substrate. It is desired for the present invention to perform the cleaning and drying before forming layers for ensuring the adherence of the layers. Further, the substrate size is not particularly restrictive in the present invention.

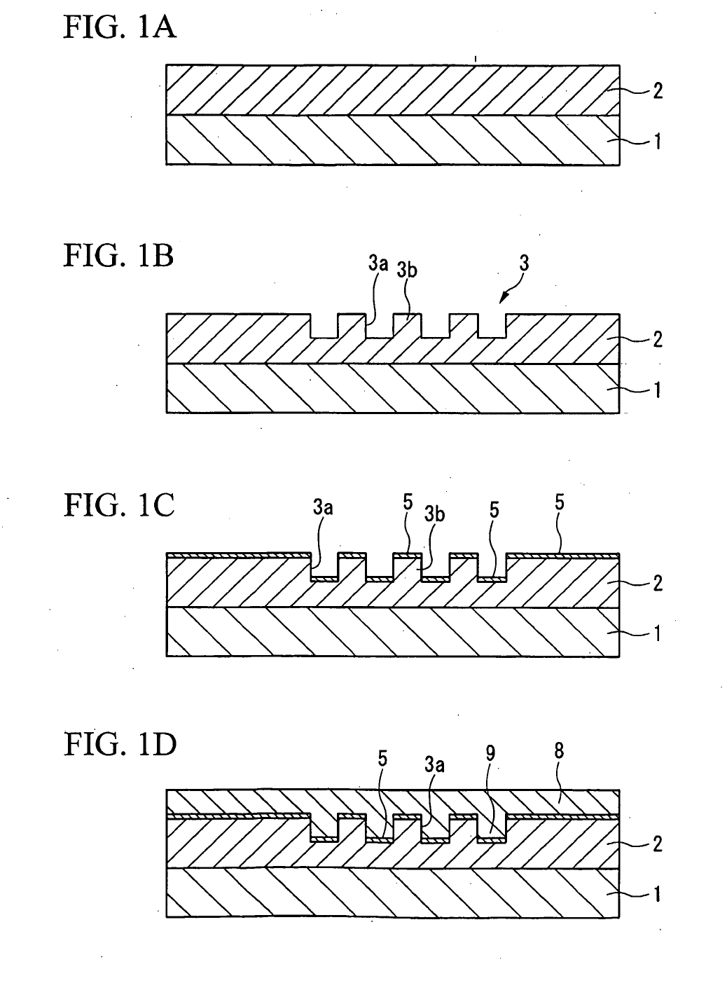

In the present invention, a concave-convex pattern designed in accordance with track intervals is formed on the surface of the substrate and, then a magnetic layer and others are formed thereon to produce a magnetic recording medium. Specifically, the following technique is used as shown in FIG. 1.

1) A thin film layer (hereafter termed a pre-emboss layer) 2 for forming a concave-convex pattern is formed on the surface of a substrate (see FIG. 1A).

2) A metal mold (stamper) having on the surface a concave-convex pattern designed for desired track intervals is placed against the surface of the pre-emboss layer 2 formed in the process 1) and pressed under high pressure to form a concave-convex pattern 3 in the form of tracks on the surface of the pre-emboss layer 2 on the substrate surface (see FIG. 1B). For example, when the substrate 1 has a disk shape, the concave-convex pattern 3 is concentric or spiral in the plane view.

The concave-convex pattern 3 consists of convex parts 3a having a width of approximately 0.2 to 0.05 μm and convex parts 3b having a width of approximately 0.05 to 0.2 μm and a depth of approximately 0.05 to 0.15 μm when the concave-convex pattern is formed on a magnetic recording medium disk applied to a magnetic recording/reproducing device such as one for a personal computer. These numbers are given by way of an example applied to magnetic recording media having the current recording densities and, therefore, not restrictive in the present invention.

3) A recording layer 5 consisting of a non-magnetic primary layer and a magnetic layer is formed on the substrate 1 having the concave-convex pattern 3 formed in the process 2) (see FIG. 1C). Here, according to the difference in dimension between the thickness of the recording layer 5 deposited on the concave-convex pattern 3 and the step magnitude of the concave-convex pattern 3, when the step magnitude of the convex-concave pattern 3 is larger, the recording layer 5 is less deposited on the inner walls of the steps of the concave-convex pattern 3 because of the process coverage. Therefore, the recording layer 5 is mainly deposited on the bottom of the concave part (groove) 3a and on the top of the convex part 3b as shown in FIG. 1C. The magnetic layer 5 used here can be a magnetic single layer or a laminate of multiple layers. Alternatively, a multi-layer recording layer or a complex having intermediate layers and multiple functional layers can be used. The recording layer 5 can have an overall thickness of approximately 0.02 to 0.20 μm.

4) A non-magnetic layer 8 such as a SiO₂ layer is deposited on the recording layer 5 to fill extremely narrow concave parts 6 formed between tracks with the non-magnetic substance (hereafter termed the filling process). Here, the concave part (groove) 3a on the surface of the magnetic recording medium is filled deeply with the non-magnetic substance to create a non-magnetic filling 9 inside the concave part 3a.

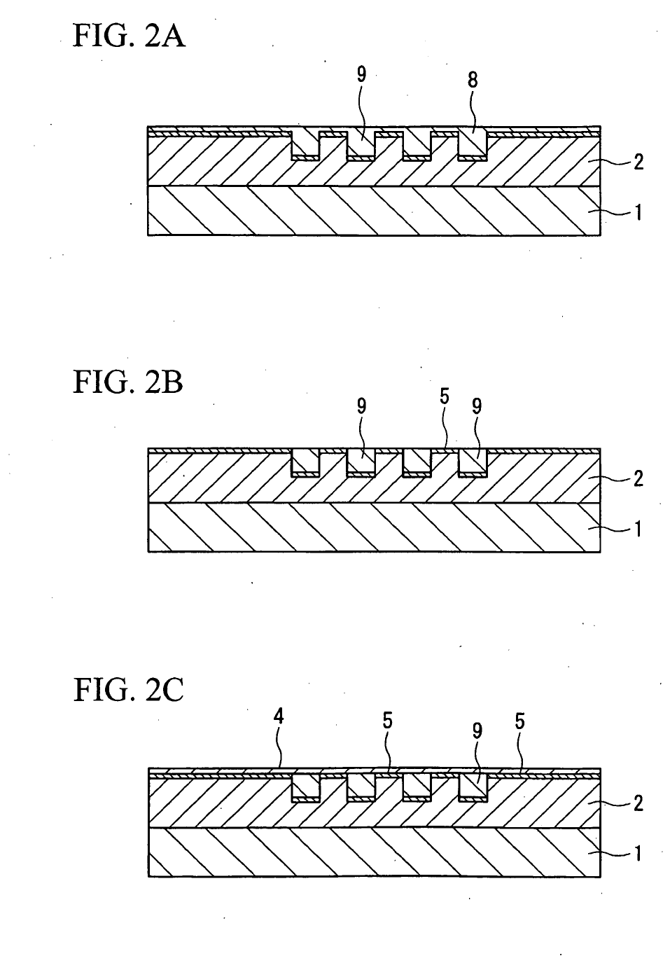

5) Then, the surface of the non-magnetic layer 8 is smoothed by, for example, polishing or dry etching (hereafter termed the smoothing process) (see FIGS. 2A and B).

Preferably, as shown in FIG. 2B, the non-magnetic layer 8 deposited on the recording layer 5 above the convex part 3b is completely removed and only the non-magnetic substance filled in the concave part 3a or the non-magnetic filling 9 remains.

6) Then, a protective layer 4 is formed (see FIG. 2C). In FIG. 2C, the non-magnetic filling 9 remains along the spiral or concentric concave part 3a in the plane view when the substrate has a disk shape.

In place of the processes 1) and 2), a stamper is directly placed against the substrate and pressed under high pressure to form a concave-convex pattern in the form of tracks on the substrate surface, enabling the same processes as shown in FIG. 1C to FIG. 2C to be performed.

In such a case, the non-magnetic filling is created in the concave part directly formed in the substrate.

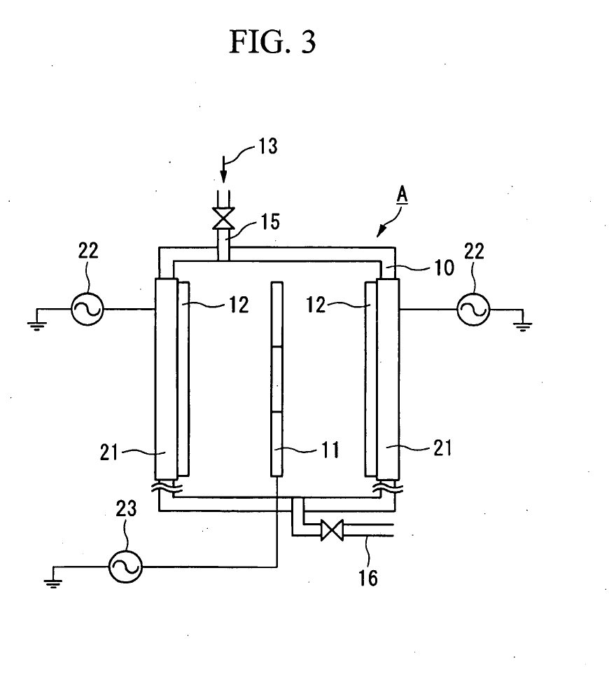

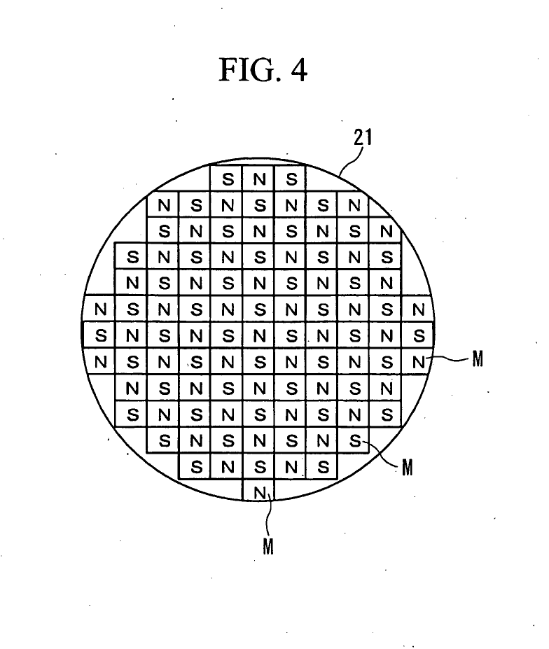

In the present invention, a film-forming apparatus used in the processes 3) and 4) can be a film-forming apparatus A having a chamber 10 in which a non magnetic substrate 11 can be introduced upright, target members 12 on either side of the non-magnetic substrate 11 and magnet plates 21 on the opposite side of the target member 12 to the non-magnetic substrate can be placed in parallel, and a high frequency power source 22 can be connected to the target members 12 to apply a high frequency voltage as shown in FIG. 3 by way of an example.

In the apparatus structure in FIG. 3, a bias power source 23 for applying high frequency bias voltage is connected to the non-magnetic substrate 11 and a direct current voltage can be applied to the target members 12 in addition to the high frequency voltage. The bias power source 23 can be eliminated.

The chamber 10 is provided with a feed port 15 having a valve for introducing a sputtering gas 13 and an exhaust pipe 16 having a valve for coupling the chamber 10 to a vacuum pump so as to create a vacuum in the chamber 10.

In this exemplary film-forming apparatus A, the inner pressure of the chamber 10 is reduced to a predetermined pressure and the sputtering gas 13 is introduced through the feed port 15 to produce plasma near the target members 12, depositing a thin film on the non-magnetic substrate 11 in the chamber 10 by sputtering.

It is preferred in this case that a high frequency voltage bias ranging from 5 to 400 MHz be applied to the non-magnetic substrate 11 by the bias power source 23 and that a higher frequency voltage be applied to the target members 12 than the bias applied to the non-magnetic substrate 11.

For example, a high frequency of 60 MHz is preferably applied to the target members 12, 12 when a high frequency of 13.56 MHz is applied to the non-magnetic substrate 11.

The magnet plates 21 are placed behind the target members 12, respectively, basically having the same function as in the magnetron sputtering.

The magnet plates 21 have on the surfaces small magnets M arranged in a fine grid with their opposite polarities alternating at regular intervals. Magnetic fluxes from these magnets M appear in a fine, complex profile.

Producing fine magnetic fields at the target members 12 of the film-forming apparatus A, these magnets M create a highly strong magnetic field near the target members 12 and produce high density plasma. This causes the target members 12 to release sputtering particles at a high ionic density. Additionally, the magnet plates 21 having the magnets M arranged as described above can be rotated during film-forming for further uniform film deposition.

In the present invention, the magnetic field created by the multiple fine magnets M and high frequency voltage applied to the target members 12 serves to ionize a larger number of particles, leading to excellent film coating rates and orientation that cannot be achieved by conventional sputtering techniques. Therefore, a thin layer can be deposited while the fine concave part (groove) previously formed on the substrate surface or on the pre-emboss surface can be preserved as it is.

The small magnets of the magnet plate of the present invention are preferably for example 5 to 30 mm in size and either rectangular or circular in cross-section. These magnets are arranged in a grid with their opposite polarities alternating at intervals of approximately 0 to 20 mm

The stamper used in the process 2) can be for example a metal plate having a fine track pattern formed by electronic line drawing techniques. The stamper should be made of a material having hardness and durability so that it can withstand the process. For example, the stamper can be made of Ni. However, the stamper can be made of any material as long as it meets the purpose described above. The stamper also can carry servo signal patterns such as burst patterns, gray code patterns, preamble patters besides tracks for recording regular data.

In the filling process 4), the non-magnetic substance can be filled for example by a dry process. Representative materials include SiO₂. However, it is not restricted as long as the material is non-magnetic and does not impair the performance of a magnetic recording medium. In the filling process, the non-magnetic material should uniformly fill the extremely fine and deep concave part (groove). Unless the filling process is performed properly, magnetic interaction between tracks may not be completely blocked and sufficient recording/reproducing properties cannot be expected. Gaps may cause contact with gases such as oxygen, causing possible adverse effect on corrosion resistance.

Therefore, the film-forming apparatus A and sputtering technique according to the present invention can be used to allow the non-magnetic substance to fill the concave part 3a at a high filling rate and deposit.

In the smoothing process 5), the concave-convex pattern on the film surface after the filling process is smoothed to a level sufficient for a magnetic recording medium. To do so, for example, chemical mechanical polish (CMP) or ion beam etching (IBE) can be used. However, no techniques are disadvantageous to the present invention as long as they can smooth the surface of a magnetic recording medium without deteriorating the performance of the magnetic recording medium.

Considering the magnetic recording/reproduction, it is advantageous for higher density magnetic recording that the magnetic head be floated as little as possible. One of the characteristics of the substrate of a magnetic recording medium is excellent smoothness. Therefore, the substrate preferably has a surface roughness (Ra) of 1 nm or smaller, even 0.5 nm or smaller, particularly 0.1 nm or smaller.

In the process 6), a protective film is formed. Generally, a thin film of diamond-like carbon is deposited by deposition techniques such as P-CVD. However, it is not restricted to this.

The protective film 4 used in the present invention is considered to be one generally used as a magnetic recording medium protective film. Besides the above, the protective layer 4 can be a carbonaceous layer such as C, hydrogenated C, nitrogenized C, amorphous C, and Si, or a generally used protective material such as SiO₂, Zr₂O₃, and TiN. The protective layer can consist of two or more layers.

The protective layer 4 used in the present invention has a thickness of 1 to 10 rn and, preferably, 1 to 5 nm. It is preferred that the protective layer 4 be as thin as possible to the extent that it still ensures durability.

It is preferable that a lubricant layer be formed on the protective layer 4. Lubricants used for the lubricant layer include fluorine lubricants, hydrocarbon lubricants, and mixtures thereof. The lubricant layer usually has a thickness of 1 to 4 nm.

The method of producing a magnetic recording medium according to the present invention can be applied to the production of other discrete track magnetic recording media. An exemplary process is described hereafter.

1) A magnetic film is deposited on a substrate by using a conventional technique to produce a magnetic recording medium.

2) A resist is applied on the surface of the magnetic recording medium, and, if necessary, this is followed by calcination to remove extra organic solvent.

3) A stamper having on the surface a concave-convex pattern designed for desired track intervals is placed against the medium surface obtained in the process 2) and pressed under high pressure so that the concave-convex pattern in the form of tracks is transferred to the resist on the medium surface (hereafter termed the imprint process).

4) The resist, protective film, and magnetic layer on the surface of the magnetic recording medium are partly removed by a technique such as dry etching or reactive ion etching. Consequently, the concave-convex pattern remains on the magnetic recording medium along the concave-convex tracks formed in the process 3) (hereafter termed the etching process).

5) A non-magnetic substance such as SiO₂ is deposited, for example, by sputtering to fill extremely narrow grooves formed between tracks with the non-magnetic substance.

6) Then, the concave-convex pattern remaining on the surface is smoothed by, for example, polishing or dry etching.

7) Finally, a protective film is deposited again.

Using sputtering in the process 5) of the present invention, the concave part formed on the magnetic recording medium can be filled deep with the non-magnetic substance, producing a magnetic recording medium having excellent electromagnetic conversion properties because magnetic interaction between tracks is blocked in a reliable and highly precise manner.

A magnetic recording device having a high recording density can be realized by a combination of the magnetic recording medium of the present invention, a driving part for driving it in the recording direction, a magnetic head consisting of a recording part and a reproducing part, a means for moving the magnetic head relative to the magnetic recording medium, and a recording/reproducing signal processing means for performing signal input to the magnetic head and reproducing output signals from the magnetic head.

With the recording tracks on the medium being physically discontinuous, the reproducing head and recording head can have nearly the same width while the reproducing head is smaller in width than the recording head in order to eliminate the influence of magnetic transition regions at the track edges in the prior art. In this way, a magnetic recording medium having sufficient reproduction output and a high S/N ratio can be realized.

Furthermore, the reproducing part of the magnetic head can be constituted by a GMR head or a TMR head so as to obtain sufficiently strong signals at higher recording densities, realizing a magnetic storing device having a high recording density.

When such a magnetic head is floated at a rate of 0.05 to 0.20 μm, which is lower than in the prior art, the output is improved and a higher device S/N ratio is obtained, providing a highly reliable magnetic storing device having a large capacity. The recording density can be further increased in combination with a signal processing circuit for maximum likelihood decoding. Then, for example, S/N ratios sufficient for recording/reproducing at a track density of 100 kTPI or larger, a linear recording density of 1000 kbpl or larger, and a recording density of 100 G bits/square inch or larger can be obtained.

### EXAMPLES

A vacuum chamber in which a HD glass substrate has been placed was vacuumed in advance to 1.0×10⁻⁵ Pa or lower. The glass substrate used was a disk made of crystallized glass containing Li₂si₂O₅ (%), Al₂O₃+K₂O (%), MGO+P₂O₅ (%), Sb₂O₃+ZnO (%) and having a surface roughness (Ra): 5 Å, an outer diameter of 65 mm, and an inner diameter of 20 mm.

A SiO₂ film as the pre-emboss layer was deposited to a thickness of 200 nm on the substrate by a conventional sputtering technique.

Then, an Ni stamper previously prepared was used for imprinting. Three stampers having a track pitch of 60 nm, 100 nm, and 200 nm, respectively, were prepared. The groove (the concave part of the groove) had a depth of 20 nm. Each stamper was used twice to create six imprints.

Among the substrates, one substrate was selected for each track pitch and a total of three substrates were heated to approximately 250° C. Then, NiAl, CrMo₆, CoCrPt, CoCr₂₀B₆Pt₈, and C protective layers and a fluorine lubricant agent were deposited in sequence. The layers were all deposited by DC sputtering. No bias voltage was applied to the substrate. The argon partial pressure was approximately 7.0×10⁻¹ Pa during the film-forming.

The final layer structure consisted of, from the top, C/CoCrBPt/CoCrPt/CrMo/NiAl/substrate. Among them, the CoCrPt comprised Co-42Cr-2Pt [atomic %]. Each layer had the following thicknesses: NiAl (a thickness of 600 Å), CrMo6 (a thickness of 100 Å), CoCr20B6PT8 (a thickness of 250 Å), and C (a thickness of 50 Å). These samples were designated as Comparative Examples 1, 2 and 3.

On the other hand, among the substrates, one substrate was selected for each track pitch and a total of three substrates were used for film-forming by sputtering according to the present invention.

Electrodes used in the sputtering process had a circular shape having a diameter of 420 mm, over which Nd—Fe—B magnets having dimensions of 10×10×12 mm 3 and a magnetic flux density of 12.1 kG near the magnetic poles were arranged in a grid at intervals of 40 mm. Adjacent magnets had their magnetic poles oriented oppositely. A 60 MHz RF power source was connected to the electrodes and 1000 W power was applied. The Ar partial pressure was adjusted for 1.3 Pa. The plasma density near the substrate was approximately 1.0×10¹¹ cm³, which had been found in another study conducted by the inventors of the present invention.

In order to follow the process above as much as possible, the substrate was heated to approximately 250° C. Then, NiAl, CrMo₆, CoCrPt, CoCr₂₀B₆Pt₈, and C protective layers and a fluorine lubricant agent were deposited in sequence. The layers were all deposited by sputtering according to the present invention.

The Ar gas partial pressure was 6 Pa, the RF applied to the targets was 1.5 kW, and the DC bias was 100 W. No bias was applied to the substrate. The deposited alloy composition and layer thickness were the same as those of Comparative Examples 1 to 3. The produced magnetic recording media were designated as Examples 1, 2, and 3.

Then, Comparative Examples 1 to 3 and Examples 1 to 3 were again introduced in the highly vacuumed chamber, in which a SiO₂ non-magnetic layer was deposited by RF sputtering. The SiO₂ non-magnetic layer was deposited to an average thickness of 300 Å.

Further, the surface was smoothed by ion beam etching. Each sample was introduced in the vacuum chamber previously vacuumed to 1×10⁻⁴ Pa. Ar gas was introduced to a partial pressure of 5 Pa. 300 W RF power was applied to each sample to etch the sample surface.

These three samples were designated as Examples 1 to 3. Examples 1 to 3 and Comparative Examples 1 to 3 were evaluated for electromagnetic conversion properties using a spin stand. Different heads were used for the respective track pitches in the evaluation.

The conditions given in Table 1 were applied. The SNR (signal-to-noise ratio) was measured in recording 750 kFCI signals for each combination.

TABLE 1

| | | reproducing | | 3T-Squash |
|---|---|---|---|---|
| | track pitch | head | SNR (dB) | (%) |
| Example 1 | 60 nm | 40 nm | 10.2 | 85.2 |
| Example 2 | 100 nm | 60 nm | 13.1 | 89.0 |
| Example 3 | 200 nm | 110 nm | 13.9 | 90.5 |
| Comparative | 60 nm | 40 nm | 5.4 | 50.5 |
| Example 1 | | | | |
| Comparative | 100 nm | 60 nm | 6.2 | 53.2 |
| Example 2 | | | | |
| Comparative | 200 nm | 110 nm | 6.3 | 55.5 |
| Example 3 | | | | |

Consequently, as shown in Table 1, significant improvements were observed in RW (recording/reproducing property) such as the SNR and Squash compared to Comparative Examples that are continuous mediums. Supposedly, this is because the concave-convex pattern was almost preserved and the tracks were sufficiently separated when the sputtering according to the present invention was used while the concave-convex pattern formed on the substrate surface was impaired by medium film-forming and the tracks were not sufficiently magnetically separated in the prior art sputtering technique.

1. A method of producing a discrete magnetic recording medium having physically discrete magnetic recording tracks and servo signal patterns on at least one surface of a non-magnetic substrate, characterized by the fact that:
the non-magnetic substrate, target members on either surface of the non-magnetic substrate, and magnetic plates on the opposite surface of each target member to the substrate are placed in parallel in a film-forming apparatus, wherein a high frequency voltage is applied to the target members, the opposite polarities
alternately occur at regular intervals on the surfaces of the magnet plates, and a sputtering gas is introduced to the film-forming apparatus to produce plasma near the target members, thereby forming a thin film on the non-magnetic substrate by sputtering.

2. The method of producing a discrete magnetic recording medium according to claim 1 characterized by the fact that said plasma near the non-magnetic substrate placed in the film-forming apparatus has a density of 1×10¹¹/cm³ or higher.

3. The method of producing a discrete magnetic recording medium according to claim 1 characterized by the fact that a high frequency voltage bias is applied to said non-magnetic substrate.

4. The method of producing a discrete magnetic recording medium according to claim 1 characterized by the fact that a direct current voltage is applied to said target members in addition to the high frequency voltage.

5. The method of producing a discrete magnetic recording medium according to claim 3 characterized by the fact that a higher frequency is applied to said target members than to said substrate.

6. The method of producing a discrete magnetic recording medium according to claim 1 characterized by the fact that said magnetic plates are rotated.

7. The method of producing a discrete magnetic recording medium according to claim 1 characterized by the fact that said non-magnetic substrate has a concave-convex pattern directly formed on at least one surface or formed on a thin film on at least one surface,

8. A magnetic recording medium produced by the method of producing a discrete magnetic recording medium according to claim 1.

9. A magnetic recording device comprising a combination of the magnetic recording medium according to claim 8, a driving part for driving the magnetic recording medium in the recording direction, a magnetic head consisting of a recording part and a reproducing part, a means for moving the magnetic head relative to the magnetic recording medium, and a recording/reproducing signal processing means for supplying input signals to the magnetic head and reproducing output signals from the magnetic head.
